(19) United States
(12) Patent Application Publication
(10) Pub. No.: US 2025/0037931 A1
(43) Pub. Date: Jan. 30, 2025

(54) CHOKE MODULE

(71) Applicant: TDK Europe GmbH, Muenchen (DE)

(72) Inventors: Shinichiro Nishizawa, Muenchen (DE); Uzzal Binit Bala, Muenchen (DE)

(21) Appl. No.: 18/709,379

(22) PCT Filed: Oct. 26, 2022
(86) PCT No.: PCT/EP2022/079872

§ 371 Date: May 10, 2024

(30) Foreign Application Priority Data
Nov. 15, 2021 (DE) 10 2021 129 686.2

(51) Int. Cl. H01F 27/33; H01F 27/24; H01F 27/28; H01F 27/29; H03H 7/01

(52) U.S. Cl. CPC H01F 27/33; H01F 27/24; H01F 27/2876; H01F 27/29; H03H 7/0115

(57) ABSTRACT

In an embodiment a choke module includes a choke with a magnetic core and at least two windings, a thermally conductive pad, and a footprint capacitor, which is a plate capacitor, and which is configured to provide a mechanical support for the choke, wherein the footprint capacitor comprises at least one first electrode layer, at least one dielectric layer and at least one second electrode layer located one above the other, wherein the choke is located on the footprint capacitor, wherein an upper surface of the footprint capacitor faces the choke, and wherein the thermally conductive pad is arranged on the upper surface of the footprint capacitor.

### CROSS-REFERENCE TO RELATED APPLICATIONS

This patent application is a national phase filing under section 371 of PCT/EP2022/079872, filed Oct. 26, 2022, which claims the priority of German patent application 102021129686.2, filed Nov. 15, 2021, each of which is incorporated herein by reference in its entirety.

### TECHNICAL FIELD

The present invention is directed to a choke module, in particular an EMC-filter module for reducing electromagnetic interference noise. The choke module may comprise a common mode choke. Such a common mode choke comprises two or more windings around a magnetic core. The windings comprise metallic wires. The material of the wires, the core and the number of winding turns define electrical parameters like inductance, losses and EMC noise attenuation. Generally, increasing the number of turns in the windings leads to an improvement of noise attenuation characteristics, at least in low frequency ranges. However, noise attenuation levels in high frequency ranges from 10 MHz to 1000 MHz, for example, are diminished due to parasitic capacitance effects between the windings. These parasitic capacitance effects increase proportionally with the number of turns in the windings and with increasing the frequency.

### BACKGROUND

EMC-filters (EMC: electromagnetic compatibility) are widely used for reducing noise in electric and electronic products, power electronic products such as inverters and DC-DC converters. In EMC-Filters, a common mode choke is electrically connected with passive components to achieve an optimum and maximum filtering and attenuation of the EMC noise level. Said passive components may comprise an inductance, a capacitance, a resistance and combinations thereof.

Application areas are the automotive field, in particular autonomous driving systems with low voltage components and all forms of electric vehicles (xEV) with high voltage components, industrial products and consumer electronic products. EMC-filter chokes are usually interconnected in an EMC filter with one or more capacitors in order to improve the damping properties both at low and at high frequencies.

As described above, it is desirable to increase the number of turns in the windings to improve the noise attenuation characteristics in the low frequency ranges. The number of turns is limited by the wire diameter for a given magnetic core. The number of turns can be increased by using a wire having a smaller wire diameter. However, a drawback of reducing the wire diameter in the windings is an increased ohmic resistance of the wire which results in the generation of heat in the winding. Therefore, for a choke having a small diameter for the wire and thus a large number of turns, thermal management is important.

### SUMMARY

Embodiments provide an improved choke module.

Embodiments relate to a choke module comprising a choke which comprises a magnetic core and at least two windings and a footprint capacitor. Preferably, a plastic baseplate, which is used in the prior art to provide mechanical support to the choke, is replaced by the footprint capacitor.

The footprint capacitor forms a plate capacitor and is configured to provide a mechanical support for the choke. The footprint capacitor comprises at least one first electrode layer, at least one dielectric layer and at least one second electrode layer located one above the other, wherein the choke is located on the footprint capacitor, wherein an upper surface of the footprint capacitor faces the choke and wherein a thermally conductive pad is arranged on the upper surface of the footprint capacitor.

The footprint capacitor may be a plate capacitor which is configured to provide mechanical support to the choke. The footprint capacitor may be electrically connected to the choke. The footprint capacitor may be arranged directly below the choke, i.e. no other elements, except for the thermally conductive pad, may be arranged between the choke and the footprint capacitor.

The thermally conductive pad may be arranged between the upper surface of the footprint capacitor and the winding. The thermally conductive pad may abut at least one winding. The thermally conductive pad may be arranged directly on the upper surface, i.e. the thermally conductive pad may be in direct contact to the upper surface. More than one thermally conductive pad may be arranged on the upper surface.

Heat generated in at least one winding of the choke may be transferred away from the choke by the thermally conductive pad. As the thermally conductive pad may improve the thermal management, i.e. the heat transfer away from the choke, it may enable the use of a wire with a small diameter in the winding. The small diameter results in a high ohmic resistance of the wire. However, as heat may be transferred away from the choke by the thermally conductive pad, overheating due to the high ohmic resistance may be prevented. A small diameter of the wire enables an increase in the number of turns in the windings which improves the noise attenuation characteristics at least in the low frequency ranges.

The footprint capacitor may have lateral dimensions which are only slightly larger than the lateral dimensions of the choke. When the footprint capacitor and the choke are circular, the respective lateral dimension may refer to the diameter of the footprint capacitor and the diameter of the choke.

The footprint capacitor can increase the attenuation of the choke module at high frequencies. By combining the thermally conductive pad and the footprint capacitor in one choke module, a good attenuation may be achieved in a large frequency range, because the thermally conductive pad may enable a high attenuation in the low frequency range by enabling the use of a large number of turns and the footprint capacitor enables a high attenuation in the high frequency range.

The choke may be a common mode choke for reducing electromagnetic interference noise.

The footprint capacitor may be formed by a printed circuit board. As an example, the footprint capacitor may be formed by an FR4-board, a flexible board or a low temperature co-fired ceramics board, which are based on glass reinforced epoxy laminate, synthetic materials and ceramics, respectively.

The first and the second electrode layers may be formed by screen printing on the insulating dielectric layer and/or etching a metallic layer, such as a copper layer, located on the insulating dielectric layer. The first and second electrodes may comprise copper or consist of copper.

The footprint capacitor may have an overall shape of a plate. A plate generally has a small thickness and much larger lateral dimensions. As an example, the smallest lateral dimension may be at least five times larger than the thickness of the plate.

The choke module may be configured to be mounted on a printed circuit board with main surfaces of the footprint capacitor and the printed circuit board parallel to each other. A mounting direction is perpendicular to the main surface of the printed circuit board.

The footprint capacitor may comprise one or more capacitors being interconnected with a choke between an input line and ground and/or an output line and ground. In particular, the filter circuit may be a so-called x-filter circuit.

The choke module with the footprint capacitor may provide high attenuation in radio bands, in a frequency range of 1 to 1000 MHz. Furthermore, adjusting the capacitance value by adjusting the area and number of layers of the footprint capacitor, improves the attenuation in specific frequency ranges within the range of 1 to 1000 MHz. In addition to that, low DC resistance and inductance can be achieved with the footprint capacitor. This has advantages for noise reduction in high frequency ranges, compared to discrete capacitors such as film and ceramic capacitors, which have higher DC resistance and inductance values and are commonly used in standard EMC filters.

The thermally conductive pad may abut at least one winding. In one embodiment, two thermally conductive pads are arranged on the upper surface of the footprint capacitor. The choke may comprise two windings and each of the thermally conductive pads abut one of the windings. The thermally conductive pads may be configured to transfer heat from the choke to the footprint capacitor.

The thermally conductive pad may comprise a thermally conductive paste. For example, the thermally conductive paste may be fluid or solid. The thermally conductive pad may comprise any material having a high temperature conductivity. As the thermally conductive pad allows to transfer heat from the choke to the footprint capacitor efficiently, it is possible to use a wire having a small diameter for the windings without generating overheating due to the increased ohmic resistance of the wire which results from the small wire diameter. In addition to the heat generated during regular operation, the heat which is generated due to the increased ohmic resistance is also transferred to the footprint capacitor by the thermally conductive pad.

The choke module may comprise a pin-shaped ground terminal which is connected to at least one first electrode layer or to at least one second electrode layer, wherein the pin-shaped ground terminal may protrude from the footprint capacitor in a direction away from the choke. The pin-shaped ground terminal may be configured to be connected mechanically, electrically and thermally to a printed circuit board.

The pin-shaped ground terminal may be configured to transfer heat away from the footprint capacitor. The heat may be transferred via the pin-shaped ground terminal to the printed circuit board. As the pin-shaped ground terminal may transfer heat away from the choke module, it enables the use of a wire with a small diameter and a higher ohmic resistance because the pin-shaped ground terminal helps to transport the heat away.

In particular, the pin-shaped ground terminal may be fixed to a ground contact or a ground surface of a printed circuit board. Heat generated in the choke module may be transferred via the pin-shaped ground terminal to the ground contact or to the ground surface of the printed circuit board.

The heat produced in the winding may also be transferred to the footprint capacitor via an input terminal and/or an output terminal. The input terminal and/or the output terminal are connected to some of the electrodes of the footprint capacitor. During the operation of the choke module, the electrodes of the footprint capacitor which are connected to the input terminal or to the output terminal may get very hot. The heat is transferred from these electrodes to a nearby grounded electrode which is connected to the pin-shaped ground terminal. Then, the heat from the grounded electrode is transferred to the pin-shaped ground terminal of the footprint capacitor. Finally, the heat is transferred via the pin-shaped ground terminal to the printed circuit board.

Further, the printed circuit board may be arranged in a housing that is actively cooled, i.e. by water or by air cooling.

In one embodiment, the choke module may comprise another thermally conductive pad which is arranged on a lower surface of the footprint capacitor which faces away from the choke. The thermally conductive pad arranged on the lower surface may be configured to transport heat away from the footprint capacitor and away from the choke module. In particular, when the choke module is assembled on a printed circuit board, the thermally conductive pad on the lower surface may face the printed circuit board and may transfer heat from the choke module to the printed circuit board.

The thermally conductive pad on the lower surface may comprise the same material as the thermally conductive pad on the upper surface.

A lateral dimension of the footprint capacitor may not be larger than 10 times a lateral dimension of the choke. Preferably, the lateral dimension of the footprint capacitor may not be larger than twice a lateral dimension of the choke. More preferably, the lateral dimension of the footprint capacitor may not be larger by more than 25% compared to a lateral dimension of the choke, even more preferably by no more than 10%.

At least one first electrode layer may comprise four separate first electrodes and at least one second electrode layer may comprise a single second electrode. Four capacitors may be formed by the four electrodes of the first electrode layer and the single electrode of the second electrode layer.

The plate capacitor may be formed as the single layer capacitor comprising exactly one first electrode layer facing the choke, one second electrode layer facing away from the choke and one dielectric layer which is sandwiched between the first electrode layer and the second electrode layer. Alternatively, the plate capacitor may comprise several first electrode layers, several second electrode layers and several dielectric layers. The electrode layers and the dielectric layers may be alternatively stacked on each other.

Further embodiments relate to an assembly comprising the above-described choke module and a printed circuit board. The choke module is mounted on the printed circuit board. Accordingly, the choke module is fixed by terminals, for example by the pin-shaped ground terminal and by input and output terminals to the printed circuit board. The terminals may be fixed to the printed circuit board by a pin-through-hole technology. The lower surface of the footprint capacitor may face a main surface of the printed circuit board. The lower surface of the footprint capacitor may be parallel to the main surface of the printed circuit board.

The pin-shaped ground terminal may be connected to a ground surface of the printed circuit board. Heat generated in the choke module may be transferred via the pin-shaped ground terminal to the ground surface of the printed circuit board.

The choke module may comprises a thermally conductive pad which is arranged on the lower surface of the footprint capacitor which faces away from the choke, wherein the thermally conductive pad which is arranged on the lower surface of the footprint capacitor is configured to transfer heat from the footprint capacitor to the printed circuit board.

The printed circuit board may be arranged in a housing that is cooled by water or air.

### BRIEF DESCRIPTION OF THE DRAWINGS

In the following, preferred embodiments of the present invention are described with reference to the figures.

FIG. 1 shows a choke module according to a first embodiment in a perspective view;

FIG. 2 shows the choke module schematically in a cross-sectional view;

FIG. 3 shows parts of the choke module in a perspective view;

FIG. 4 shows an upper surface of a footprint capacitor of the choke module in a perspective view;

FIG. 5 shows the choke module arranged on a printed circuit board;

FIG. 6 shows a footprint capacitor in a top view;

FIG. 7 shows the footprint capacitor in a bottom view;

FIG. 8 shows a footprint capacitor in a cross-sectional view;

FIG. 9 shows the equivalent circuit diagram of the common mode choke filter module; and

FIGS. 10 and 11 show perspective views of a choke module according to a second embodiment.

In the figures, elements of the same structure and/or functionality may be referenced by the same reference numerals. It is to be understood that the embodiments shown in the figures are illustrative and are not necessarily drawn to scale.

### DETAILED DESCRIPTION OF ILLUSTRATIVE EMBODIMENTS

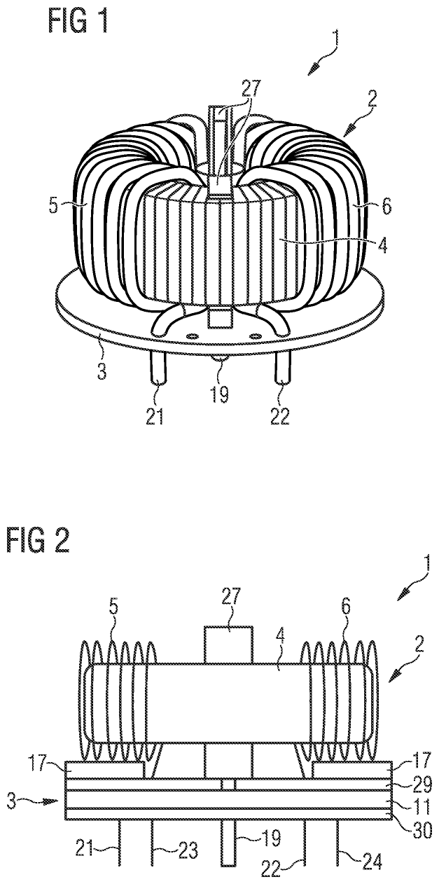

Each of FIGS. 1 to 4 shows a choke module or parts of a choke module according to a first embodiment.

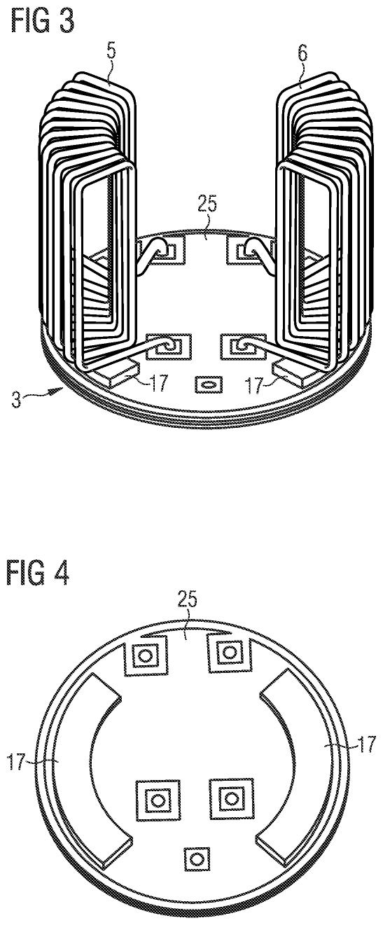

FIG. 1 shows the choke module 1 comprising a choke 2 located on a footprint capacitor 3 in a perspective view. The choke 2 comprises a magnetic core 4 and two windings 5, 6 on the magnetic core 4. FIG. 2 shows the choke module 1 schematically in a cross-sectional view. FIG. 3 shows the footprint capacitor 3 and the two windings 5, 6 in a perspective view. The magnetic core of the choke is not shown in FIG. 3 for a better illustration of the other elements of the choke module. FIG. 4 shows an upper surface of the footprint capacitor 3 in a perspective view.

The choke 2 is a common mode choke for reducing electromagnetic interference noise, for example. In particular, the choke 2 serves as a filter for providing electromagnetic compatibility (EMC).

Each of the windings 5, 6 of the choke has an input terminal 21, 22 and an output terminal 23, 24. The input signal is provided to the input terminals 21, 22 and the filtered output signal is provided at the output terminals 23, 24. The terminals 21-24 may be pin-shaped and fixed to a printed circuit board by pin-through-hole mounting, for example. The choke module further comprises a pin-shaped ground terminal 19 that may be configured to be connected to ground.

The choke 2 is arranged and fixed on the footprint capacitor 3. The footprint capacitor 3 is formed as a plate capacitor. A thermally conductive pad 17 is arranged on a surface of the footprint capacitor 3 which faces the choke 2. The surface of the footprint capacitor 3 which faces the choke 2 is referred to as the upper surface of the footprint capacitor 3. In particular, two thermally conductive pads 17 are arranged on the upper surface of the footprint capacitor 3. In the embodiment shown in FIGS. 1 to 4, the thermally conductive pads 17 are C-shaped. However, other shapes of the thermally conductive pads are also possible.

Each of the thermally conductive pads 17 is arranged directly below one of the windings 5, 6. One of the thermally conductive pads 17 is arranged directly below the first winding 5 and the other of the thermally conductive pads 17 is arranged directly below the second winding 6. The shape of the thermally conductive pads 17 is adopted to the shape of the windings 5, 6, i.e. the thermally conductive pads 17 on the upper surface and the windings 5, 6 have the same shape. When seen in a top view, the windings 5, 6 form a C-shape and the thermally conductive pads 17 also form a C-shape. The top view is a view perpendicular to the upper face of the footprint capacitor 3.

The footprint capacitor 3 supports the choke 2 mechanically. As an example, the windings 5, 6 may be located directly on the thermally conductive pads 17 arranged on the upper surface of the footprint capacitor 3. The choke 2 may be additionally or alternatively supported on the footprint capacitor 3 by ends of the windings 5, 6.

The lateral dimensions of the footprint capacitor 3 are not much larger than the lateral dimensions of the choke 2. The footprint capacitor 3 may be shaped as a thin plate or a thin disc.

A fixation element 27 may fix the choke 2 on the footprint capacitor 3. The fixation element 27 may be attached to the footprint capacitor 3 by snap-fitting, for example. The fixation element 27 may also be an integral part of the footprint capacitor 3. The choke 2 may be fixed to the fixation element 27 by snap-fitting, for example.

The footprint capacitor 3 has not only a support functionality but also a capacitor functionality. In particular, the footprint capacitor 3 comprises a dielectric layer 11 sandwiched between a first electrode layer 29 and a second electrode layer 30. The dielectric layer 11 and the electrodes 12-16 form one or more capacitors. The first electrode layer 29 may comprise several separate electrodes 12, 13, 14, 15 and the second electrode layer may comprise a single second electrode 16. A top dielectric cover layer 25 may be arranged on the first electrode layer 29. A bottom dielectric cover layer 28 may be arranged on a surface of the second electrode layer 30 facing away from the choke 2.

The dielectric layer 11 may comprise a plastic material or may consist of a plastic material. The dielectric layer 11 may comprise or consist of an epoxy resin. In particular, the dielectric layer 11 may comprise or consist of an FR4-material. The capacitor plate 3 may be a printed circuit board.

The electrodes 12-16 are conductive plates fixed to the dielectric layer 11. The electrodes 12-16 may be also applied to the dielectric layer 11 by screen printing and/or galvanic processes. The electrodes 12-16 may comprise or consist of copper.

In the shown choke module 1, the choke 2 is horizontally mounted, i.e. a symmetry axis of the round magnetic core 4 is perpendicular to the upper surface of the footprint capacitor 3. In other embodiments, the choke 2 may be vertically mounted, i.e. the symmetry axis of the round magnetic core 4 may be parallel to the upper surface of the footprint capacitor 3.

The footprint capacitor 3 also has a functionality in the thermal management of the choke module 1 which will be described in the following. During operation of the choke 2, heat is generated in the windings 5, 6. Heat generated in the windings 5, 6 is transferred to the footprint capacitor 3 by the thermally conductive pads 17 arranged on the upper surface of the footprint capacitor 3. The thermally conductive pads 17 directly abut the windings 5, 6.

The thermally conductive pads 17 comprises a material which has a high temperature conductivity. For example, the thermally conductive pads 17 can comprise a thermally conductive paste. In particular, the thermally conductive pads 17 can comprise a fluid thermally conductive paste or a solid thermally conductive paste.

The thermally conductive pads 17 are configured to transfer heat generated in the windings 5, 6 away from the choke 2 to the footprint capacitor 3.

Additionally, heat is transferred from the choke 2 via the input terminals 21, 22 and the output terminals 23, 24. The input terminals 21, 22 and the output terminals 23, 24 are connected to the electrodes 12-15 of the footprint capacitor and to the printed circuit board. Thereby, heat is transferred by the input terminals 21, 22 and the output terminals 23, 24 directly to the printed circuit board and to electrodes 12-15 of the footprint capacitor. Thereby, the electrodes 12-15 are heated. In the footprint capacitor 3, the electrodes 12-15 heat up the grounded electrode 16 which is arranged close to the electrodes 12-15 and which is connected to the pin-shaped ground terminal 19. When the pin-shaped ground terminal 19 is connected to a ground surface of a printed circuit board, heat is transferred via the pin-shaped ground terminal 19 to the printed circuit board.

The choke module 1 is configured to be arranged on a printed circuit board 26, as shown in FIG. 5. In particular, the pin-shaped ground terminal 19 can be connected to a ground surface of the printed circuit board 26 by a pin-through-hole technology. The pin-shaped ground terminal 19 comprises a material which has a high thermal conductivity. When the pin-shaped ground terminal 19 is connected to the ground surface of the printed circuit board 26, heat is transferred from the footprint capacitor 3 via the pin-shaped ground terminal 19 to the printed circuit board 26. Accordingly, the pin-shaped ground terminal 19 is configured to transfer heat away from the footprint capacitor 3 and, therefore, away from the choke module 1. Additionally, heat is transferred from the choke module 1 to the printed circuit board by the input terminals 21, 22 and by the output terminals 23, 24.

The printed circuit board 26 can be arranged in a housing that is actively cooled, for example by water cooling and/or by air cooling. This active cooling can further improve the thermal management of the choke module 1.

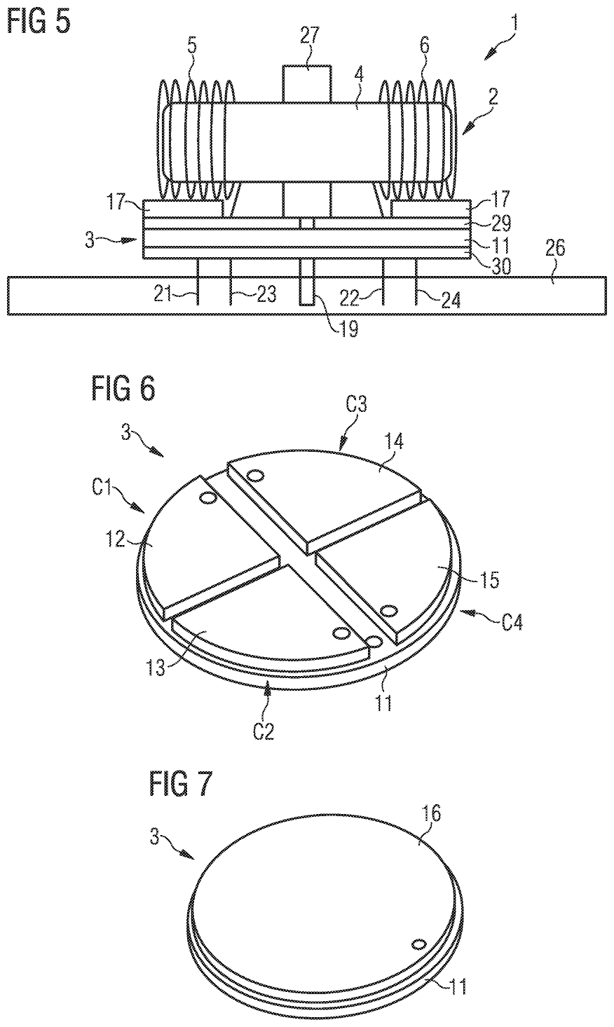

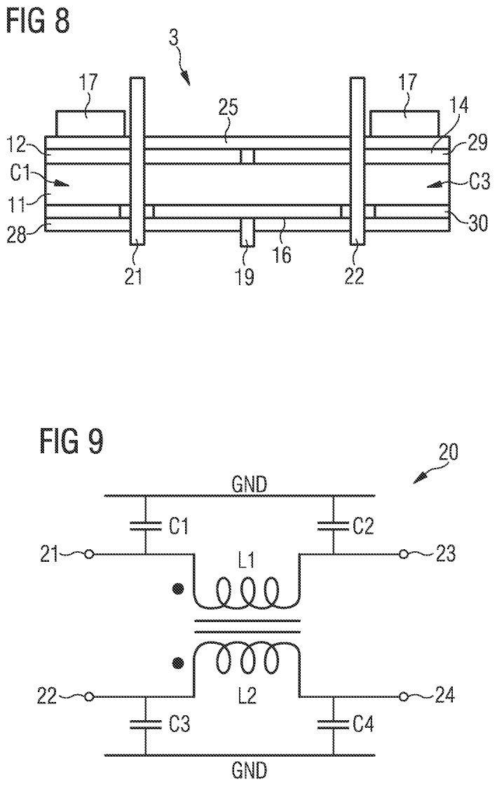

FIG. 6 shows a footprint capacitor 3 in a top view and FIG. 7 shows the footprint capacitor 3 in a bottom view. FIG. 8 shows the footprint capacitor 3 in a cross-sectional view. In FIGS. 6 and 7, a circular footprint capacitor 3 is shown. Alternatively, the shape can be also elliptic or oval or rectangular or any other shape.

As can be seen in FIG. 6, the first electrode layer 29 comprises four first electrodes 12-15 formed as four separate regions on the upper side of the dielectric layer 11. In particular, each of the first electrodes 12-15 has a shape of a quarter of a circle.

Each of the input and output terminals 21-24 is electrically connected to one of the first electrodes 12-15. In particular, the input terminals 21, 22 are connected to adjacent first electrodes 12, 14 in a first row. The output terminals 23, 24 are connected to adjacent first electrodes 13, 15 in a second row. Depending on the number of input and output terminals 21-24, the number of first electrodes 12-15 may be different. Depending on the specific circuitry, it is also possible to connect several input terminals and output terminals to the same first electrode. Overall, the first electrodes 12-15 are the footprint pattern of the footprint capacitor 3, matching the input terminals 21, 22 and output footprint capacitors 23, 24 of the choke 2.

The first electrodes 12-15 cover the top surface of the dielectric layer 11 almost entirely, apart from the insulating gaps between the first electrodes 12-15 and small insulating regions on the lateral edges of the top surface.

As can be seen in FIG. 7, the second electrode layer 30 has a single second electrode 16 with a circular shape. The second electrode 16 covers almost the entire bottom surface of the dielectric layer 11, apart from small insulating regions on the lateral edges of the bottom surface.

The second electrode 16 may be connected to ground. For example, the second electrode 16 may be connected by the pin-shaped ground terminal 19 to a ground surface of the printed circuit board 26.

FIG. 8 shows a footprint capacitor 3 with a single dielectric layer 11 in a cross-sectional view. The input terminals 21, 22 are connected to electrodes 12, 14 in the first electrode layer and extend downwards through the second electrode 16 while being insulated from the second electrode 16.

A corresponding connection structure applies for the output terminals 23, 24 which are not visible in this view. The output terminals 23, 24 are connected with the first electrodes 13, 15.

The input terminals 21, 22 and the output terminals 23, 24 protrude from a lower surface of the footprint capacitor 3.

The second electrode layer 30 may be covered by a bottom dielectric cover layer 28 or a different insulation material to provide electric insulation. Also the first electrode layer 29 may be covered by a top dielectric cover layer 25 or a different insulation material.

FIG. 8 shows that the pin-shaped ground terminal 19 is electrically connected with the second electrode 16 and extends downwards from the footprint capacitor 3.

The footprint capacitor 3 may have a multilayer configuration. In this case, the footprint capacitor 3 may comprise several layers of dielectric layers and electrodes layers arranged one above the other.

The outer dimensions of the choke module 1 may be similar to the outer dimensions of a choke module comprising a usual support plate. Thus, replacing the support plate by the shown footprint capacitor 3 with capacitor functionality does not lead to an increase of the size of the choke module.

FIG. 9 shows the equivalent circuit diagram of the choke module 1 comprising the footprint capacitor 3.

The input terminals 21, 22 are connected via an inductance L1, L2 provided by the windings 5, 6 to the output terminals 23, 24. Four capacitors C1, C2, C3, C4 are provided by the first electrodes 12-15, the dielectric layer 11 and the second electrode 16. First capacitors C1, C3 are connected at the input side between an input line and ground. The second capacitors C2, C4 are connected at the output side between an output line and ground. Such capacitor connected between input or output line and ground are so-called Y-capacitors.

The shown equivalent circuit of the common mode choke filter 20 is a π-filter circuit for each of the lines.

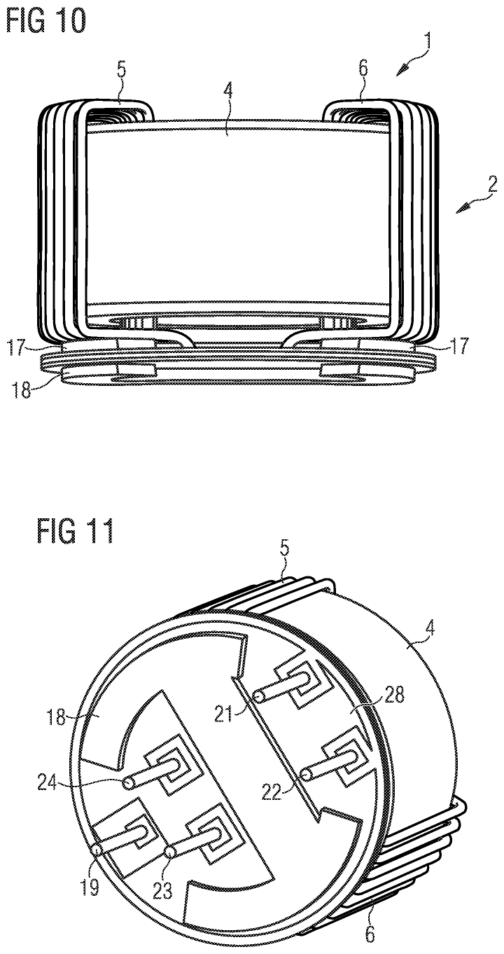

FIGS. 10 and 11 show perspective views of a choke module 1 according to a second embodiment. The second embodiment differs from the choke module 1 according to the first embodiment in that a further thermally conductive pad 18 is arranged at the lower surface of the footprint capacitor 3. The lower surface of the footprint capacitor 3 is the surface which faces away from the choke 2. The lower surface faces towards the printed circuit board 26, when the choke module 1 is assembled on the printed circuit board.

The thermally conductive pad 18 arranged on the lower surface may comprise the same material as the thermally conductive pads 17 arranged on the upper surface. The thermally conductive pad 18 arranged on the lower surface may comprise a material having a high temperature conductivity. The thermally conductive pad 18 arranged on the lower surface may be H-shaped. Other shapes are also possible for the thermally conductive pad 18.

The thermally conductive pad 18 arranged on the lower surface is configured to transfer heat from the footprint capacitor 3 to the printed circuit board 26 when the choke module is assembled on the printed circuit board. Accordingly, the thermally conductive pad 18 arranged on the lower surface further improves the heat transfer away from the choke 2.

According to the second embodiment, heat is transferred away from the choke 2 via the pin-shaped ground terminal 19, via the input terminals 21, 22, via the output terminals 23, 24, via the thermally conductive pads 17 on the upper surface and via the thermally conductive pad 18 arranged on the lower surface. Each of the pin-shaped ground terminal 19 and the thermally conductive pads 17, 18 transfer heat away from the choke module 1 and towards the ground surface of the printed circuit board 26. Thus, in the choke module 1 of the second embodiment the heat transfer away from the choke module is improved compared to the first embodiment, in which no thermally conductive pad 18 is arranged on the lower surface of the footprint capacitor.

As already described above for the first embodiment, the electrodes of the first electrode layer 29 are heated by heat transferred in the input and output terminals 21-24. The electrodes of the first electrode layer 29 are arranged near the grounded electrode 16 of the second electrode layer 30. Thus, heat is transferred from the electrodes 11-15 to the electrode 16 and, further, the heat is transferred via the pin-shaped ground terminal 19 connected to the electrode 16 to the ground surface of the printed circuit board.

1-16. (canceled)

17. A choke module comprising:
a choke with a magnetic core and at least two windings;
a thermally conductive pad; and
a footprint capacitor, which is a plate capacitor, and which is configured to provide a mechanical support for the choke,
wherein the footprint capacitor comprises at least one first electrode layer, at least one dielectric layer and at least one second electrode layer located one above the other,
wherein the choke is located on the footprint capacitor,
wherein an upper surface of the footprint capacitor faces the choke, and
wherein the thermally conductive pad is arranged on the upper surface of the footprint capacitor.

18. The choke module according to claim 17, wherein the thermally conductive pad abuts at least one of the windings.

19. The choke module according to claim 17, wherein the thermally conductive pad is configured to transfer heat from the choke to the footprint capacitor.

20. The choke module according to claim 17, wherein the thermally conductive pad comprises a thermally conductive paste.

21. The choke module according to claim 17, further comprising:
a pin-shaped ground terminal connected to at least one second electrode layer,
wherein the pin-shaped ground terminal protrudes from the footprint capacitor in a direction away from the choke.

22. The choke module according to claim 21, wherein the pin-shaped ground terminal is configured to transfer heat away from the footprint capacitor.

23. The choke module according to claim 17, further comprising:
input terminals and output terminals, which are connected to at least one first electrode layer,
wherein the input terminals and output terminals protrude from the footprint capacitor in a direction away from the choke.

24. The choke module according to claim 23, wherein the input terminals and output terminals are configured to transfer heat from the choke to the footprint capacitor.

25. The choke module according to claim 17, further comprising:
a thermally conductive pad arranged on a lower surface of the footprint capacitor, which faces away from the choke.

26. The choke module according to claim 25, wherein the thermally conductive pad, which is arranged on the lower surface of the footprint capacitor, is configured to transfer heat away from the footprint capacitor.

27. The choke module according to claim 17, wherein the footprint capacitor comprises several first electrode layers, several second electrode layers and several dielectric layers.

28. The choke module according to claim 17, wherein the choke module is a common mode choke configured to reduce electromagnetic interference noise.

29. The choke module according to claim 17, wherein the thermally conductive pad and the windings have the same shape.

30. An assembly comprising:
the choke module according to claim 17; and
a printed circuit board,
wherein the choke module is mounted on the printed circuit board.

31. The assembly according to claim 30,
wherein the choke module comprises a pin-shaped ground terminal connected to at least one second electrode layer,
wherein the pin-shaped ground terminal is connected to a ground surface of the printed circuit board, and
wherein the pin-shaped ground terminal is configured to transfer heat from the footprint capacitor to the printed circuit board.

32. The assembly according to claims 30,
wherein the choke module comprises a thermally conductive pad, which is arranged on a lower surface of the footprint capacitor, which faces away from the choke, and
wherein the thermally conductive pad, which is arranged on the lower surface of the footprint capacitor, is configured to transfer heat from the footprint capacitor to the printed circuit board.

33. The assembly according to claim 30,
wherein the choke module comprises input terminals and output terminals, which are connected to at least one first electrode layer,
wherein the input terminals and output terminals are connected to the printed circuit board, and
wherein the input terminal and the output terminals are configured to transfer heat from the choke to the footprint capacitor and to the printed circuit board.
